(19) United States
(12) Patent Application Publication
(10) Pub. No.: US 2017/0135230 A1
(43) Pub. Date: May 11, 2017

(54) DISPLAY UNIT WATERPROOF STRUCTURE

(71) Applicant: LITEMAX ELECTRONICS INC., New Taipei City (TW)

(72) Inventor: TIEN-TENG YANG, NEW TAIPEI CITY (TW)

(21) Appl. No.: 14/933,191

(22) Filed: Nov. 5, 2015

(51) Int. Cl. H05K 5/00; H05K 5/02; H05K 5/06

(52) U.S. Cl. CPC H05K 5/0017; H05K 5/069; H05K 5/0217

(57) ABSTRACT

A display unit waterproof structure for use with an outdoor display unit to prevent water from intruding thereto is introduced. The display unit waterproof structure includes a plurality of blind via elements arranged at the periphery of a casing of the outdoor display unit; a plurality of resilient strips arranged at the periphery of the casing and each having at least a through hole corresponding in position to the blind via elements; an abutting portion annularly disposed at the periphery of a rear plate of the outdoor display unit, corresponding in position to the resilient strips, and having a plurality of fixing holes corresponding to the through holes and the blind via elements, respectively; and a plurality of seal fixing elements penetrating the fixing holes and the through holes to thereby be fixed to the blind via elements, respectively, such that the casing and rear plate shorten resilient strips.

### FIELD OF TECHNOLOGY

The present invention relates to waterproof apparatuses and more particularly to a display unit waterproof structure for preventing water from intruding into an outdoor display unit.

### BACKGROUND

A conventional waterproof structure for use with a conventional outdoor display unit is formed by laminating an integrally formed ring against a rear plate and the back of the outdoor display unit. However, due to the limitation of the dimensions of the conventional ring, if the outdoor display unit is overly large, it is not only difficult to form the integrally formed ring, but the integrally formed ring is likely to deform to the detriment of its waterproof effect.

Moreover, the rear plate and the back of the outdoor display unit undergo lamination by being fastened in place. As a result, rainwater intrudes readily into the outdoor display unit through the fastening junction of the rear plate and the back of the outdoor display unit to the detriment of its waterproof effect.

Accordingly, it is imperative to provide a waterproof structure for use with an outdoor display unit such that the water structure is easy to manufacture, suitable for use with outdoor display units of different dimensions, unlikely to deform, and effective in preventing water from intruding into the outdoor display unit through the fastening junction of a rear plate and the back of the outdoor display unit.

### SUMMARY

In view of the aforesaid drawbacks of the prior art, it is an objective of the present invention to provide a display unit waterproof structure which is easy to manufacture, suitable for use with outdoor display units of different dimensions, unlikely to deform, and effective in preventing water from intruding into the outdoor display unit through the fastening junction of a rear plate and the back of the outdoor display unit.

In order to achieve the above and other objectives, the present invention provides a display unit waterproof structure adapted for use with an outdoor display unit. The display unit waterproof structure comprises: a plurality of blind via elements arranged at a periphery of a casing of the outdoor display unit; a plurality of resilient strips arranged at a periphery of the casing and each having at least a through hole corresponding in position to the blind via elements, respectively; an abutting portion annularly disposed at a periphery of a rear plate of the outdoor display unit, corresponding in position to the resilient strips, and having a plurality of fixing holes corresponding in position to the through holes and the blind via elements, respectively; and a plurality of seal fixing elements penetrating the fixing holes and the through holes to thereby get fixed to the blind via elements, respectively, such that the casing and the rear plate shorten the resilient strips.

Regarding the display unit waterproof structure, the resilient strips are waterproof

Regarding the display unit waterproof structure, the resilient strips are each laterally provided with an adhesive layer.

The display unit waterproof structure further comprises a plurality of protuberances received in the through holes, respectively, to limit an amount by which a length of the resilient strips is reduced by the casing and the rear plate.

Regarding the display unit waterproof structure, the protuberances are each connected to the abutting portion or top openings of the blind via elements.

Regarding the display unit waterproof structure, the protuberances are annular.

In conclusion, due to the aforesaid configuration of the display unit waterproof structure of the present invention, the display unit waterproof structure is easy to manufacture, suitable for use with outdoor display units of different dimensions, unlikely to deform, and effective in preventing water from intruding into the outdoor display unit through the fastening junction of a rear plate and the back of the outdoor display unit.

### BRIEF DESCRIPTION

Objectives, features, and advantages of the present invention are hereunder illustrated with specific embodiments in conjunction with the accompanying drawings, in which:

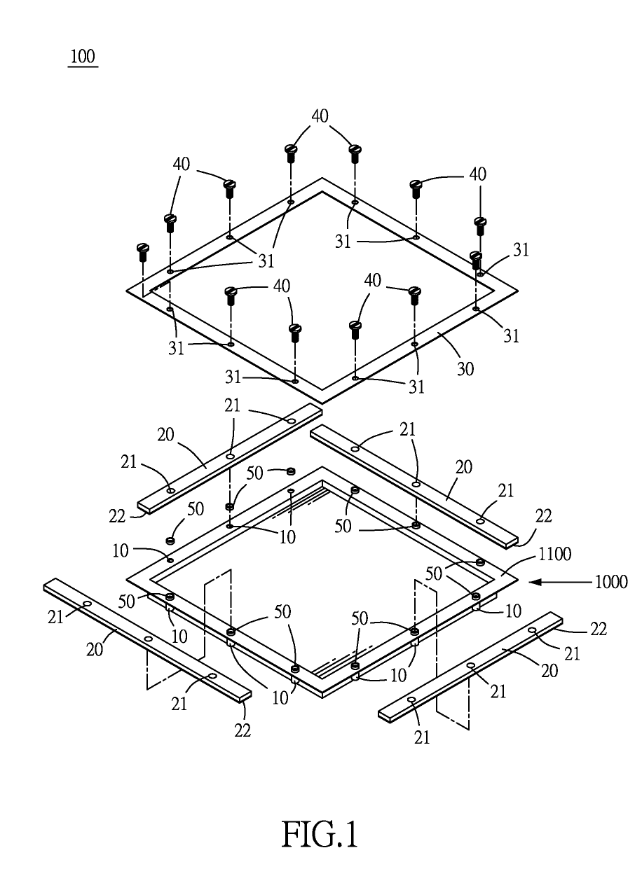

FIG. 1 is an exploded view of a display unit waterproof structure of the present invention;

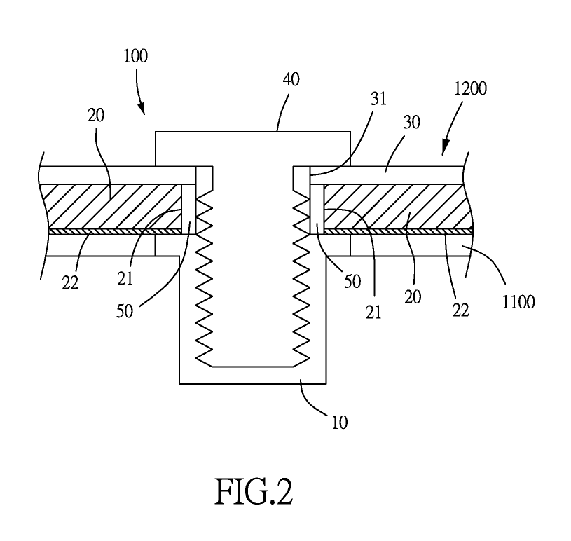

FIG. 2 is a cross-sectional view of the display unit waterproof structure of the present invention;

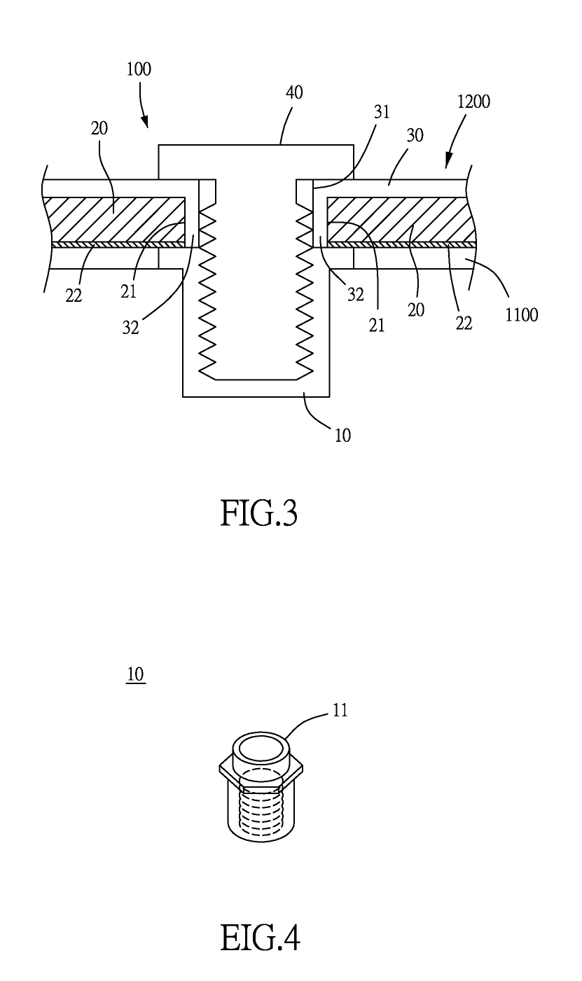

FIG. 3 is a schematic view of the display unit waterproof structure of the present invention, showing that protuberances are connected to an abutting portion; and

FIG. 4 is a schematic view of the display unit waterproof structure of the present invention, showing that protuberances are connected to blind via elements, respectively.

### DETAILED DESCRIPTION

Referring to FIG. 1 and FIG. 2, the present invention provides a display unit waterproof structure 100 for use with an outdoor display unit 1000. The display unit waterproof structure 100 comprises a plurality of blind via elements 10, a plurality of resilient strips 20, an abutting portion 30 and a plurality of seal fixing elements 40.

The blind via elements 10 are arranged at the periphery of a casing 1100 of the outdoor display unit 1000 and preferably formed by engagement, pressing, adhesion or welding. The resilient strips 20 are arranged at the periphery of the casing 1100 and each have at least a through hole 21. In an embodiment of the present invention, the through holes 21 correspond in position to the blind via elements 20. The resilient strips 20 are waterproof and are preferably made of foam plastic strips, such as the ones manufactured by 3M, but the present invention is not limited thereto. The abutting portion 30 is annularly disposed at the periphery of a rear plate 1200 of the outdoor display unit 1000 and corresponds in position to the resilient strips 20. The abutting portion 30 has a plurality of fixing holes 31. The fixing holes 31 correspond in position to the through holes 21 and the blind via elements 10, respectively. The seal fixing elements 40 penetrate the fixing holes 31 and the through holes 21 to thereby get fixed to the blind via elements 10, respectively, such that the casing 1100 and the rear plate 1200 shorten the resilient strips 20. Preferably, the seal fixing elements 40 are screws.

Referring to FIG. 2, when the seal fixing elements 40 penetrate the fixing holes 31 and the through holes 21 to thereby get fixed to the blind via elements 10, respectively, such that the casing 1100 and the rear plate 1200 shorten the resilient strips 20, there is not any gap between the casing 1100 and the resilient strips 20, nor is there any gap between the abutting portion 30 and the resilient strips 20. Moreover, with the seal fixing elements 40 penetrating the through holes 21 of the resilient strips 20, respectively, water from the fixing holes 31 is stopped at the through holes 21 of the resilient strips 20 and is unlikely to enter any gap between the casing 1100 and the resilient strips 20 or any gap between the abutting portion 30 and the resilient strips 20. Since the display unit waterproof structure 100 comprises the blind via elements 10, water from the fixing holes 31 is not only stopped at the through holes 21 of the resilient strips 20 but also confined to the blind via elements 10, such that the water is unlikely to enter the outdoor display unit 1000. The aforesaid structures together achieve a waterproof effect.

Since the display unit waterproof structure 100 comprises a plurality of resilient strips 20, the display unit waterproof structure 100 suits outdoor display units of different dimensions. Moreover, with the resilient strips 20 being arranged annularly, the display unit waterproof structure 100 is unlikely to deform.

Moreover, the resilient strips 20 are each laterally provided with an adhesive layer 22 whereby the resilient strips 20 are fixed in place better. Referring to FIG. 1 and FIG. 2, the adhesive layer 22 is disposed at the resilient strips 20 in a manner that the adhesive layer 22 is positioned proximate to the casing 1100, but the present invention is not limited thereto. In a variant embodiment of the present invention, the resilient strips 20 are positioned proximate to the abutting portion 30.

Referring to FIG. 1 and FIG. 2, to prevent the casing 1100 and the rear plate 1200 from overly shortening the resilient strips 20 when the seal fixing elements 40 penetrate the fixing holes 31 and the through holes 21 to get fixed to the blind via elements 10, respectively, the display unit waterproof structure 100 further comprises a plurality of protuberances 50 received in the through holes 21, respectively. Referring to FIG. 2, due to the limitation of the height of the protuberances 50, the abutting portion 30 at the rear plate 1200 is prevented from overly shortening the resilient strips 20 whenever the seal fixing elements 40 are fixed in place; hence, the protuberances 50 limit the amount by which the length of the resilient strips 20 is reduced by the casing 1100 and the rear plate 1200.

Referring to FIG. 3, to facilitate a manufacturing process, it is feasible to form a plurality of protuberances 32 by a pressing process as soon as the fixing holes 31 are formed. Unlike the separate protuberances 50 shown in FIG. 2, the protuberances 32 and the fixing holes 31 are integrally formed, thereby reducing the manufacturing costs and time.

Referring to FIG. 4, protuberances 11 are directly connected to top openings of the blind via elements 10, respectively, to reduce the manufacturing costs and time. Preferably, the protuberances 11 are annularly disposed at the top openings of the blind via elements 10, respectively.

In conclusion, due to the aforesaid configuration of the display unit waterproof structure of the present invention, the display unit waterproof structure is easy to manufacture, suitable for use with outdoor display units of different dimensions, unlikely to deform, and effective in preventing water from intruding into the outdoor display unit through the fastening junction of a rear plate and the back of the outdoor display unit. Moreover, the protuberances prevent the resilient strips from being overly shortened and thus damaged, thereby extending the service life of the resilient strips.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A display unit waterproof structure, for use with an outdoor display unit, the display unit waterproof structure comprising:
a plurality of blind via elements arranged at a periphery of a casing of the outdoor display unit;
a plurality of resilient strips arranged at a periphery of the casing and each having at least a through hole corresponding in position to the blind via elements, respectively;
an abutting portion annularly disposed at a periphery of a rear plate of the outdoor display unit, corresponding in position to the resilient strips, and having a plurality of fixing holes corresponding in position to the through holes and the blind via elements, respectively; and
a plurality of seal fixing elements penetrating the fixing holes and the through holes to thereby get fixed to the blind via elements, respectively, such that the casing and the rear plate shorten the resilient strips.

2. The display unit waterproof structure of claim 1, wherein the resilient strips are waterproof

3. The display unit waterproof structure of claim 2, wherein the resilient strips are each laterally provided with an adhesive layer.

4. The display unit waterproof structure of claim 1, wherein the resilient strips are each laterally provided with an adhesive layer.

5. The display unit waterproof structure of claim 1, further comprising a plurality of protuberances received in the through holes, respectively, to limit an amount by which a length of the resilient strips is reduced by the casing and the rear plate.

6. The display unit waterproof structure of claim 2, further comprising a plurality of protuberances received in the through holes, respectively, to limit an amount by which a length of the resilient strips is reduced by the casing and the rear plate.

7. The display unit waterproof structure of claim 3, further comprising a plurality of protuberances received in the through holes, respectively, to limit an amount by which a length of the resilient strips is reduced by the casing and the rear plate.

8. The display unit waterproof structure of claim 4, further comprising a plurality of protuberances received in the through holes, respectively, to limit an amount by which a length of the resilient strips is reduced by the casing and the rear plate.

9. The display unit waterproof structure of claim 5, wherein the protuberances are each connected to one of the abutting portion and top openings of the blind via elements.

10. The display unit waterproof structure of claim 6, wherein the protuberances are each connected to one of the abutting portion and top openings of the blind via elements.

11. The display unit waterproof structure of claim 7, wherein the protuberances are each connected to one of the abutting portion and top openings of the blind via elements.

12. The display unit waterproof structure of claim 8, wherein the protuberances are each connected to one of the abutting portion and top openings of the blind via elements.

13. The display unit waterproof structure of claim 5, wherein the protuberances are annular.

14. The display unit waterproof structure of claim 6, wherein the protuberances are annular.

15. The display unit waterproof structure of claim 7, wherein the protuberances are annular.

16. The display unit waterproof structure of claim 8, wherein the protuberances are annular.
